(19) United States
(12) Patent Application Publication
(10) Pub. No.: US 2025/0068076 A1
(43) Pub. Date: Feb. 27, 2025

(54) RESIST UNDERLAYER COMPOSITION AND METHOD OF FORMING PATTERNS USING THE COMPOSITION

(71) Applicant: SAMSUNG SDI CO., LTD., Yongin-si (KR)

(72) Inventors: Seongjin KIM, Suwon-si (KR); Jaeyeol BAEK, Suwon-si (KR); Soonhyung KWON, Suwon-si (KR); Byeonggyu HWANG, Suwon-si (KR); Hwayoung JIN, Suwon-si (KR); Eunsu LEE, Suwon-si (KR); Ahra CHO, Suwon-si (KR); Yoojeong CHOI, Suwon-si (KR); Sungwoo JUNG, Suwon-si (KR)

(21) Appl. No.: 18/776,047

(22) Filed: Jul. 17, 2024

(30) Foreign Application Priority Data
Aug. 23, 2023 (KR) 10-2023-0110687

(51) Int. Cl. G03F 7/11; C08G 73/06; C09D 179/04

(52) U.S. Cl. CPC G03F 7/11; C08G 73/0666; C09D 179/04

(57) ABSTRACT

Disclosed are a resist underlayer composition, and a method of forming a pattern using the resist underlayer composition. The resist underlayer composition includes a polymer including a structural unit represented by Chemical Formula 1, and a solvent. The definitions of Chemical Formula 1 are as described in the specification.

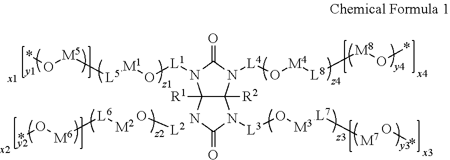

### CROSS-REFERENCE TO RELATED APPLICATION

The present application claims priority to and the benefit of Korean Patent Application No. 10-2023-0110687, filed on Aug. 23, 2023, in the Korean Intellectual Property Office, the entire content of which is hereby incorporated by reference.

### BACKGROUND

### 1. Field

Embodiments of this disclosure relate to a resist underlayer composition, and a method of forming patterns using the same.

### 2. Description of the Related Art

Recently, a semiconductor industry has developed to an ultra-fine technique having a pattern of several to several tens of nanometers in size. Such ultrafine techniques benefit from effective lithographic techniques.

The lithographic technique is a processing method that involves coating a photoresist layer on a semiconductor substrate such as, for example, a silicon wafer to form a thin film, irradiating activating radiation such as, for example, ultraviolet rays through a mask pattern on which the device pattern is drawn, developing it to obtain a photoresist pattern, and etching the substrate using the obtained photoresist pattern as a protective film to form a fine pattern corresponding to the pattern on the surface of the substrate.

As semiconductor patterns become increasingly finer, a thickness of the photoresist layer should be thin, and accordingly, a thickness of the resist underlayer should also be thin. The resist underlayer should not collapse the photoresist pattern even if it is thin, should have good adhesion to the photoresist, and should be formed to have a uniform (or substantially uniform) thickness. The resist underlayer should have a high refractive index and low extinction coefficient for the light used in photolithography and a faster etch rate than the photoresist layer.

### SUMMARY

The resist underlayer composition according to some embodiments of the present disclosure provides a resist underlayer in which adhesion between the resist and the resist underlayer is improved and resist pattern collapse does not occur even during a fine patterning process.

The resist underlayer composition according to some embodiments provides a resist underlayer having an excellent etch rate and pattern formation ability by improving crosslinking characteristics and coating uniformity.

Some embodiments provide a method of forming a pattern using the resist underlayer composition.

A resist underlayer composition according to some embodiments includes a polymer including a structural unit represented by Chemical Formula 1, and a solvent:

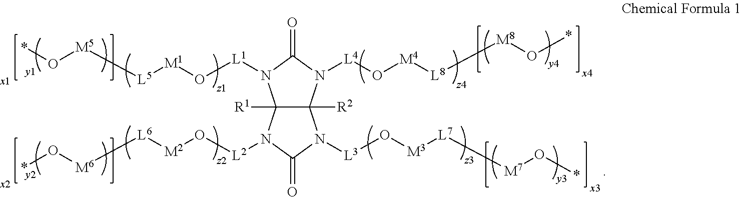

In Chemical Formula 1,
L¹ to L⁴ are each independently a substituted or unsubstituted C1 to C20 alkyl group or a substituted or unsubstituted C1 to C20 alkylene group,
L⁵ to L⁸ are each independently a single bond (e.g., a single covalent bond), a substituted or unsubstituted C1 to C20 alkyl group, a substituted or unsubstituted C1 to C20 alkylene group, a substituted or unsubstituted C2 to C20 alkenyl group, a substituted or unsubstituted C2 to C20 alkenylene group, a substituted or unsubstituted C2 to C20 alkynyl group, a substituted or unsubstituted C2 to C20 alkynylene group, a substituted or unsubstituted C3 to C20 cycloalkyl group, a substituted or unsubstituted C3 to C20 cycloalkylene group, a substituted or unsubstituted C6 to C30 aryl group, a substituted or unsubstituted C6 to C30 arylene group, or a combination thereof,
M¹ to M⁸ are each independently a single bond (e.g., a single covalent bond), —C(═O)—, —OC(═O)—, or a combination thereof,
x1 to x4 are each independently 0 or 1, provided that at least two selected from x1 to x4 are each 1,
y1 to y4 are each independently 0 or 1,
z1 to z4 are each independently 0 or 1,
R¹ and R² are each independently hydrogen, deuterium, a hydroxy group, a substituted or unsubstituted C1 to C10 alkoxy group, a substituted or unsubstituted C1 to C10 alkyl group, a substituted or unsubstituted C2 to C10 alkenyl group, a substituted or unsubstituted C2 to C10 alkynyl group, a substituted or unsubstituted C1 to C10 heteroalkyl group, a substituted or unsubstituted C1 to C10 heteroalkenyl group, a substituted or unsubstituted C1 to C10 heteroalkynyl group, a substituted or unsubstituted C3 to C20 cycloalkyl group, or a combination thereof, and
* is a linking point with other structural units.

In some embodiments, in Chemical Formula 1, L¹ to L⁴ are each independently a substituted or unsubstituted C1 to C10 alkyl group or a substituted or unsubstituted C1 to C10 alkylene group, L⁵ to L⁸ are each independently a single bond (e.g., a single covalent bond), a substituted or unsubstituted C1 to C10 alkyl group, a substituted or unsubstituted C1 to C10 alkylene group, a substituted or unsubstituted C2 to C10 alkenyl group, a substituted or unsubstituted C1 to C10 alkenylene group, a substituted or unsubstituted C2 to C10 alkynyl group, a substituted or unsubstituted C2 to C10 alkynylene group, or a combination thereof,
M¹ to M⁸ are each independently a single bond (e.g., a single covalent bond), —C(═O)—, or a combination thereof,
two selected from x1 to x4 are each 1, the other two are each 0, and
R¹ and R² are each independently hydrogen, deuterium, a hydroxy group, a substituted or unsubstituted C1 to C10 alkoxy group, a substituted or unsubstituted C1 to C10 alkyl group, or a combination thereof.

In some embodiments, in Chemical Formula 1, L⁵ to L⁸ are each independently a single bond (e.g., a single covalent bond), a substituted or unsubstituted C1 to C10 alkyl group, a substituted or unsubstituted C1 to C10 alkylene group, or a combination thereof, M¹ to M⁸ are each independently a single bond (e.g., a single covalent bond), —C(═O)—, or a combination thereof, and R¹ and R² are hydrogen.

In some embodiments, in Chemical Formula 1, x1 and x4 are each 1, and x2 and x3 are each 0.

In some embodiments, the structural unit represented by Chemical Formula 1 is represented by one or more selected from Chemical Formula 1-1 and Chemical Formula 1-2:

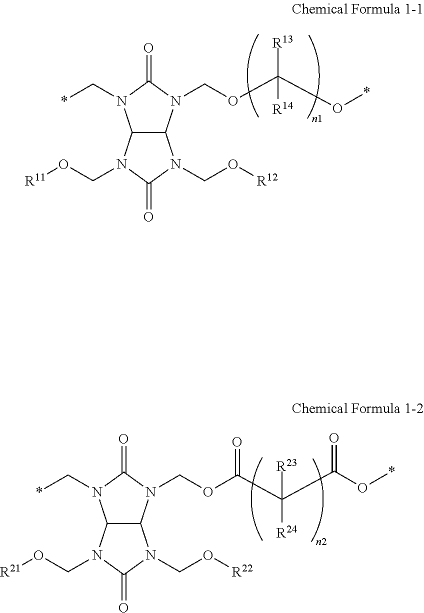

wherein, in Chemical Formula 1-1 and Chemical Formula 1-2,
R¹¹, R¹², R²¹, and R²² are each independently hydrogen, deuterium, or a substituted or unsubstituted C1 to C10 alkyl group,
R¹³, R¹⁴, R²³, and R²⁴ are each independently hydrogen, deuterium, a hydroxy group, a substituted or unsubstituted C1 to C10 alkyl group, a substituted or unsubstituted C1 to C10 alkoxy group, or a combination thereof,
n1 and n2 are each independently one of integers from 1 to 10, and
* is a linking point.

A weight average molecular weight of the polymer may be about 1,000 g/mol to about 300,000 g/mol.

The polymer may be included in an amount of about 0.1 wt % to about 50 wt % based on a total weight of the resist underlayer composition.

The resist underlayer composition may further include one or more additional polymers selected from an acrylic resin, an epoxy resin, a novolac-based resin, a glycoluril-based resin, and a melamine-based resin.

The resist underlayer composition may further include additives such as a surfactant, a thermal acid generator, a photo acid generator, a plasticizer, or a combination thereof.

According to some embodiments, a method of forming a pattern includes forming a film to be etched on a substrate, coating the resist underlayer composition according to some embodiments on the film to be etched to form a resist underlayer, forming a photoresist pattern on the resist underlayer, and etching the resist underlayer and the film to be etched sequentially using the photoresist pattern as an etch mask.

The resist underlayer composition according to some embodiments improves the adhesion between the resist and the resist underlayer, and can provide a resist underlayer in which the resist pattern collapse does not occur even during a fine patterning process.

The resist underlayer composition according to some embodiments can provide a resist underlayer having an excellent etch rate and pattern formation ability by improving crosslinking characteristics and coating uniformity.

### BRIEF DESCRIPTION OF DRAWINGS

The accompanying drawings, together with the specification, illustrate embodiments of the subject matter of the present disclosure, and, together with the description, serve to explain principles of embodiments of the subject matter of the present disclosure.

FIGS. 1-6 are cross-sectional views illustrating a method of forming a pattern using a resist underlayer composition according to some embodiments.

### DETAILED DESCRIPTION

Example embodiments of the present disclosure will hereinafter be described in more detail, and may be easily performed by a person skilled in the art upon reviewing the present disclosure. However, the subject matter of this disclosure may be embodied in many different forms and is not construed as limited to the example embodiments set forth herein.

In the accompanying drawings, the thicknesses of layers, films, panels, regions, etc., may be exaggerated for clarity and like reference numerals designate like elements throughout the specification. It will be understood that if an element such as a layer, film, region, or substrate is referred to as being “on” another element, it may be directly on the other element or intervening elements may also be present. In contrast, if an element is referred to as being “directly on” another element, there are no intervening elements present.

As used herein, if a definition is not otherwise provided, ‘substituted’ refers to replacement of a hydrogen atom of a compound by a substituent selected from a deuterium, a halogen atom (F, Br, Cl, or I), a hydroxy group, a nitro group, a cyano group, an amino group, an azido group, an amidino group, a hydrazino group, a hydrazono group, a carbonyl group, a carbamyl group, a thiol group, an ester group, a carboxyl group or a salt thereof, a sulfonic acid group or a salt thereof, a phosphoric acid or a salt thereof, a C1 to C30 alkyl group, a C2 to C30 alkenyl group, a C2 to C30 alkynyl group, a C6 to C30 aryl group, a C7 to C30 arylalkyl group, a C1 to C30 alkoxy group, a C1 to C20 heteroalkyl group, a C3 to C20 heteroarylalkyl group, a C3 to C30 cycloalkyl group, a C3 to C15 cycloalkenyl group, a C6 to C15 cycloalkynyl group, a C2 to C30 heterocyclic group, and a combination thereof.

In some embodiments, two adjacent substituents of the substituted halogen atom (F, Br, Cl, or I), hydroxy group, nitro group, cyano group, amino group, azido group, amidino group, hydrazino group, hydrazono group, carbonyl group, carbamyl group, thiol group, ester group, carboxyl group or salt thereof, sulfonic acid group or salt thereof, phosphoric acid or salt thereof, C1 to C30 alkyl group, C2 to C30 alkenyl group, C2 to C30 alkynyl group, C6 to C30 aryl group, C7 to C30 arylalkyl group, C1 to C30 alkoxy group, C1 to C20 heteroalkyl group, C3 to C20 heteroarylalkyl group, C3 to C30 cycloalkyl group, C3 to C15 cycloalkenyl group, C6 to C15 cycloalkynyl group, or C2 to C30 heterocyclic group may be fused together with each other to form a ring.

As used herein, if a definition is not otherwise provided, “hetero” refers to one including 1 to 3 heteroatoms selected from N, O, S, Se, and P.

As used herein, “aryl group” refers to a group having at least one hydrocarbon aromatic moiety, and broadly hydrocarbon aromatic moieties linked by a single bond (e.g., a single covalent bond) and a non-aromatic fused ring including hydrocarbon aromatic moieties fused directly or indirectly. An aryl group may be monocyclic, polycyclic, or fused polycyclic (e.g., rings sharing adjacent pairs of carbon atoms) functional group.

As used herein, “heterocyclic group” includes a heteroaryl group, and a cyclic group including at least one heteroatom selected from N, O, S, P, and Si instead of carbon © of a cyclic compound such as an aryl group, a cycloalkyl group, a fused ring thereof, or a combination thereof. If the heterocyclic group is a fused ring, each or entire ring of the heterocyclic group may include at least one heteroatom.

In some embodiments, a substituted or unsubstituted aryl group and/or a substituted or unsubstituted heterocyclic group may be a substituted or unsubstituted phenyl group, a substituted or unsubstituted naphthyl group, a substituted or unsubstituted anthracenyl group, a substituted or unsubstituted phenanthryl group, a substituted or unsubstituted naphthacenyl group, a substituted or unsubstituted pyrenyl group, a substituted or unsubstituted biphenyl group, a substituted or unsubstituted terphenyl group, a substituted or unsubstituted quaterphenyl group, a substituted or unsubstituted chrysenyl group, a substituted or unsubstituted triphenylenyl group, a substituted or unsubstituted perylenyl group, a substituted or unsubstituted indenyl group, a substituted or unsubstituted furanyl group, a substituted or unsubstituted thiophenyl group, a substituted or unsubstituted pyrrolyl group, a substituted or unsubstituted pyrazolyl group, a substituted or unsubstituted imidazolyl group, a substituted or unsubstituted triazolyl group, a substituted or unsubstituted oxazolyl group, a substituted or unsubstituted thiazolyl group, a substituted or unsubstituted oxadiazolyl group, a substituted or unsubstituted thiadiazolyl group, a substituted or unsubstituted pyridinyl group, a substituted or unsubstituted pyrimidinyl group, a substituted or unsubstituted pyrazinyl group, a substituted or unsubstituted triazinyl group, a substituted or unsubstituted benzofuranyl group, a substituted or unsubstituted benzothiophenyl group, a substituted or unsubstituted benzimidazolyl group, a substituted or unsubstituted indolyl group, a substituted or unsubstituted quinolinyl group, a substituted or unsubstituted isoquinolinyl group, a substituted or unsubstituted quinazolinyl group, a substituted or unsubstituted quinoxalinyl group, a substituted or unsubstituted naphthyridinyl group, a substituted or unsubstituted benzoxazinyl group, a substituted or unsubstituted benzothiazinyl group, a substituted or unsubstituted acridinyl group, a substituted or unsubstituted phenazinyl group, a substituted or unsubstituted phenothiazinyl group, a substituted or unsubstituted phenoxazinyl group, a substituted or unsubstituted fluorenyl group, a substituted or unsubstituted dibenzofuranyl group, a substituted or unsubstituted dibenzothiophenyl group, a substituted or unsubstituted carbazolyl group, a pyridoindolyl group, a benzopyridooxazinyl group, a benzopyridothiazinyl group, a 9,9-dimethyl-9,10-dihydroacridinyl group, a combination thereof, or a combined fused ring of the foregoing groups, but is not limited thereto.

As used herein, if specific definition is not otherwise provided, the term “combination” refers to mixing and/or copolymerization.

Additionally, as used herein, “polymer” may include both oligomers and polymers.

As used herein, if a definition is not otherwise provided, “weight average molecular weight” may be measured by dissolving a powder sample (the column may be Shodex LF-804 and the standard sample may be Shodex polystyrene) in tetrahydrofuran (THF) and using Agilent Technologies' 1200 series Gel Permeation Chromatography (GPC).

As used herein, if a definition is not otherwise provided, ‘*’ refers to a linking point of the structural unit of the compound or the moiety of the compound.

In the semiconductor industry, there is an effort to reduce the size of chips. Consequently, a line width of the resist patterned utilizing lithography technology should be reduced to a level of several tens of nanometers, and the pattern formed in this way is used to transfer the pattern to a lower material by using an etching process on a lower substrate. However, as the pattern size of the resist becomes smaller, a height (e.g., aspect ratio) of the resist that can withstand the line width is limited, and accordingly, the resists may not have suitable or sufficient resistance in the etching step. Therefore, a resist underlayer has been used to compensate for this if a thin resist material is used, if the substrate to be etched is thick, and/or if a deep pattern is required.

The resist underlayer should become thinner as the thickness of the resist becomes thinner, and the photoresist pattern should not collapse even if the resist underlayer is thin. For this purpose, the resist underlayer should have excellent adhesion to the photoresist. In embodiments, in forming a thin resist underlayer, the crosslinking characteristics and coating uniformity of the resist underlayer composition should be improved.

A resist underlayer composition according to some embodiments includes a polymer including a structural unit represented by Chemical Formula 1, and a solvent:

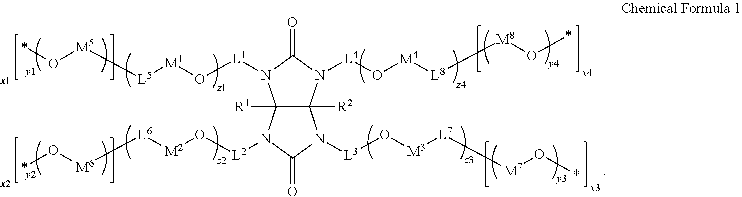

In Chemical Formula 1, L¹ to L⁴ are each independently a substituted or unsubstituted C1 to C20 alkyl group or a substituted or unsubstituted C1 to C20 alkylene group, L⁵ to L⁸ are each independently a single bond (e.g., a single covalent bond), a substituted or unsubstituted C1 to C20 alkyl group, a substituted or unsubstituted C1 to C20 alkylene group, a substituted or unsubstituted C2 to C20 alkenyl group, a substituted or unsubstituted C2 to C20 alkenylene group, a substituted or unsubstituted C2 to C20 alkynyl group, a substituted or unsubstituted C2 to C20 alkynylene group, a substituted or unsubstituted C3 to C20 cycloalkyl group, a substituted or unsubstituted C3 to C20 cycloalkylene group, a substituted or unsubstituted C6 to C30 aryl group, a substituted or unsubstituted C6 to C30 arylene group, or a combination thereof,
M¹ to M⁸ are each independently a single bond (e.g., a single covalent bond), —C(═O)—, —OC(═O)—, or a combination thereof,
x1 to x4 are each independently 0 or 1, provided that at least two selected from x1 to x4 are each 1,
y1 to y4 are each independently 0 or 1,
z1 to z4 are each independently 0 or 1,
R¹ and R² are each independently hydrogen, deuterium, a hydroxy group, a substituted or unsubstituted C1 to C10 alkoxy group, a substituted or unsubstituted C1 to C10 alkyl group, a substituted or unsubstituted C2 to C10 alkenyl group, a substituted or unsubstituted C2 to C10 alkynyl group, a substituted or unsubstituted C1 to C10 heteroalkyl group, a substituted or unsubstituted C1 to C10 heteroalkenyl group, a substituted or unsubstituted C1 to C10 heteroalkynyl group, a substituted or unsubstituted C3 to C20 cycloalkyl group, or a combination thereof, and
* is a linking point with other structural units.

The polymer, as shown in the structural unit represented by Chemical Formula 1, includes a glycoluril structure formed of two cyclic urea groups fused by one chain linking the same two carbons. The glycoluril structure may form a sp²-sp² bond between polymers by including a carbonyl group (—C(═O)—) and two nitrogen atoms linked thereto including a lone pair of electrons. While the present disclosure is not limited by any particular mechanism or theory, it is believed that the underlayer composition including the polymer has high electron density and improves density of a thin film formed thereof, thereby providing an ultra-thin film having a dense structure. In some embodiments, efficiency of the composition may be improved during the exposure.

In some embodiments, the substituent and/or the linking group linked to nitrogen (N) of the glycoluril in the structural unit may be adjusted to control crosslinking characteristics and coating uniformity of the resist underlayer composition including the polymer. For example, if the linking group bonded with N of the glycoluril includes a functional group such as a lone pair of electrons such as —O—, —C(═O)—, and/or the like and/or includes a hydrophilic substituent such as a hydroxy group or an alkoxy group, etc., the polymer may have more crosslinkable sites. In some embodiments, a resist underlayer formed of a composition including the polymer having more crosslinking sites may have a denser structure. In some embodiments, the linking group linked to N of the glycoluril may include a hydrophobic group such as an alkylene group, an alkenylene group, an alkynylene group, and/or the like, which may improve coating properties and an etch rate of a composition including many of such hydrophobic groups. In some embodiments, the substituent or the linking group in the structural unit represented by Chemical Formula 1 may be adjusted to optimize or improve the crosslinking characteristics and/or coating uniformity of the composition including the polymer. For the same reason, an etch rate and pattern-forming capability of a resist underlayer formed of the composition may be improved.

If x1 to x4 of Chemical Formula 1 are each 1, each of four terminals extending from the glycoluril is linked to each different structural unit, for example if at least two or more selected from x1 to x4 are each 1, two or more different structural units may be linked. Accordingly, the resist underlayer formed of the composition including the polymer may have a much denser structure. In some embodiments, if two or more selected from x1 to x4 are each 1, the coating uniformity of the composition including the polymer may be further improved.

In Chemical Formula 1, L¹ to L⁴ are each independently a substituted or unsubstituted C1 to C10 alkyl group or a substituted or unsubstituted C1 to C10 alkylene group, for example a substituted or unsubstituted C1 to C5 alkyl group or a substituted or unsubstituted C1 to C5 alkylene group, for example a substituted or unsubstituted methyl group or methylene group, or a substituted or unsubstituted ethyl group or ethylene group, but are not limited thereto. By including such a linking group, fluidity of the polymer including the structural unit may be improved and solubility in the solvent may be increased.

L⁵ to L⁸ are each independently a single bond (e.g., a single covalent bond), a substituted or unsubstituted C1 to C10 alkyl group, a substituted or unsubstituted C1 to C10 alkylene group, a substituted or unsubstituted C2 to C10 alkenyl group, a substituted or unsubstituted C2 to C10 alkenylene group, a substituted or unsubstituted C2 to C10 alkynyl group, a substituted or unsubstituted C2 to C10 alkynylene group, or a combination thereof, for example single bond (e.g., a single covalent bond), a substituted or unsubstituted C1 to C10 alkyl group, a substituted or unsubstituted C1 to C10 alkylene group, or a combination thereof, but are not limited thereto. L⁵ to L⁸ may exist as a monovalent group if x1 to x4 are each 0, and they may exist as a divalent group if x1 to x4 are each 1.

In Chemical Formula 1, R¹ and R² are each independently hydrogen, deuterium, a hydroxy group, a substituted or unsubstituted C1 to C10 alkoxy group, a substituted or unsubstituted C1 to C10 alkyl group, or a combination thereof, for example hydrogen, or deuterium, but are not limited thereto.

In some embodiments, in Chemical Formula 1, L¹ to L⁴ are each independently a substituted or unsubstituted methyl or methylene group, and L⁵ to L⁸ are each independently a single bond (e.g., a single covalent bond), a substituted or unsubstituted C1 to C10 alkyl group, a substituted or unsubstituted C1 to C10 alkylene group, or a combination thereof, M¹ to M⁸ are each independently a single bond (e.g., a single covalent bond), —C(═O)—, or a combination thereof, and R¹ and R² are hydrogen, but are not limited thereto.

In Chemical Formula 1, x1 to x4 are each independently 0 or 1, two or more selected from x1 to x4 are each 1, or three or more selected from x1 to x4 are each 1, for example, two selected from x1 to x4 are each 1, for example, x1 to x4 may each be and x2 and x3 may each be 0, for example x1 and x2 may each be 1 and x3 and x4 may each be 0, or for example x1 and x3 may each be 1 and x2 and x4 may each be 0. For example, x1 and x4 are each 1, and x2 and x3 are each 0, but are not limited to thereto.

As an example, Chemical Formula 1 may be expressed by one or more selected from Chemical Formula 1-1 and Chemical Formula 1-2:

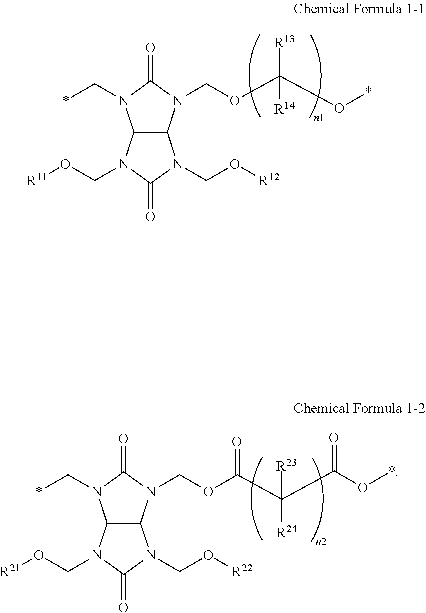

In Chemical Formula 1-1 and Chemical Formula 1-2, R¹¹, R¹², R²¹, and R²² are each independently hydrogen, deuterium, or a substituted or unsubstituted C1 to C10 alkyl group, R¹³, R¹⁴, R²³, and R²⁴ are each independently hydrogen, deuterium, a hydroxy group, a substituted or unsubstituted C1 to C10 alkyl group, a substituted or unsubstituted C1 to C10 alkoxy group, or a combination thereof, and n1 and n2 are each independently one selected from integers of 1 to 10.

In some embodiments, R¹¹, R¹², R²¹, and R²² are each independently a substituted or unsubstituted C1 to C5 alkyl group, for example a substituted or unsubstituted methyl group, or a substituted or unsubstituted butyl group, but are not limited thereto.

In some embodiments, R¹³, R¹⁴, R²³, and R²⁴ are each independently hydrogen, deuterium, a hydroxy group, a substituted or unsubstituted C1 to C5 alkyl group, and for example hydrogen, deuterium, or a hydroxy group, but are not limited thereto.

In some embodiments, n1 and n2 are each independently, one selected from integers of 1 to 5, for example one selected from integers of 1 to 3, and for example an integer selected from 1 or 2, but are not limited thereto.

The polymer may have a weight average molecular weight of about 1,000 g/mol to about 300,000 g/mol, for example about 3,000 g/mol to about 200,000 g/mol, for example about 3,000 g/mol to about 100,000 g/mol, for example about 3,000 g/mol to about 90,000 g/mol, for example about 3,000 g/mol to about 70,000 g/mol, for example about 3,000 g/mol to about 70,000 g/mol, for example about 3,000 g/mol to about 50,000 g/mol, for example about 5,000 g/mol to about 50,000 g/mol, or, for example, about 5,000 g/mol to about 30,000 g/mol, but is not limited thereto. By having a weight average molecular weight within the above ranges, a carbon content and solubility in the solvent of the resist underlayer composition including the polymer may be adjusted and/or optimized or improved.

In some embodiments, the polymer may be included in an amount of about 0.1 wt % to about 50 wt % based on a total weight of the resist underlayer composition. In some embodiments, the polymer may be included in an amount of about 10 wt % to about 50 wt %, for example about 20 wt % to about 50 wt %, for example about 20 wt % to about 40 wt %, or, for example about 20 wt % to about 30 wt %, but is not limited thereto. By including the polymer within the above ranges in the composition, the thickness, coating uniformity of the resist underlayer may be adjusted.

The resist underlayer composition according to some embodiments may include a solvent. The solvent is not particularly limited as long as it has suitable or sufficient solubility and/or dispersibility for the polymer and compound according to some embodiments, but may be, for example, propylene glycol, propylene glycol diacetate, methoxypropanediol, diethylene glycol, diethylene glycol butylether, tri (ethylene glycol) monomethylether, propylene glycol monomethylether, propylene glycol monomethylether acetate, cyclohexanone, ethyllactate, gamma-butyrolactone, N,N-dimethyl formamide, N,N-dimethyl acetamide, methylpyrrolidone, methylpyrrolidinone, methyl 2-hydroxyisobutyrate, acetylacetone, ethyl 3-ethoxypropionate, or a combination thereof.

The resist underlayer composition according to some embodiments may further include one or more additional polymers selected from an acrylic resin, an epoxy resin, a novolac-based resin, a glycoluril-based resin, and a melamine-based resin, in addition to the polymer, compound, and solvent, but is not limited thereto.

The resist underlayer composition according to some embodiments may further include an additive including a surfactant, a thermal acid generator, a plasticizer, or a combination thereof.

The surfactant may be used to improve coating defects that occur as the solid content increases if forming a resist underlayer. For example, the surfactant may be an alkylbenzenesulfonic acid salt, an alkylpyridinium salt, polyethylene glycol, a quaternary ammonium salt, etc., but is not limited thereto.

The thermal acid generator may be, for example, an acidic compound such as p-toluenesulfonic acid, trifluoromethanesulfonic acid, pyridinium p-toluenesulfonate, salicylic acid, sulfosalicylic acid, citric acid, benzoic acid, hydroxybenzoic acid, naphthalenecarboxylic acid, and/or benzoin tosylate, 2-nitrobenzyltosylate, and/or other organic sulfonic acid alkyl esters, but is not limited thereto.

The plasticizer is not particularly limited, and various suitable types (or kinds) of plasticizers generally used in the art may be used. Examples of the plasticizer may include low molecular weight compounds such as phthalic acid esters, adipic acid esters, phosphoric acid esters, trimellitic acid esters, and citric acid esters, and polyether-based, polyester-based, and polyacetal-based compounds.

The additive may be included in an amount of about 0.001 to about 40 parts by weight based on 100 parts by weight of the resist underlayer composition. By including it within the above range, solubility may be improved without (or substantially without) changing the optical properties of the resist underlayer composition.

According to some embodiments, a resist underlayer manufactured using the aforementioned resist underlayer composition is provided. The resist underlayer may be, for example, obtained by coating the aforementioned resist underlayer composition on a substrate and then curing through a heat treatment process.

Hereinafter, a method of forming a pattern using the aforementioned resist underlayer composition will be described with reference to FIGS. 1-6.

FIGS. 1-6 are cross-sectional views for explaining a method of forming a pattern using the resist underlayer composition according to the present disclosure.

Referring to FIG. 1, first, an object to be etched is prepared. An example of the object to be etched may be a thin film 102 on a semiconductor substrate 100. Hereinafter, only embodiments where the object to be etched is the thin film 102 will be described, but the present disclosure is not limited thereto. The surface of the thin film 102 is pre-cleaned to remove contaminants remaining on the thin film 102. The thin film 102 may be, for example, a silicon nitride film, a polysilicon film, and/or a silicon oxide film.

Subsequently, the aforementioned resist underlayer composition is coated on the surface of the cleaned thin film 102 using a spin coating method.

Then, drying and baking processes are performed to form a resist underlayer 104 on the thin film. The baking treatment may be performed at about 100° C. to about 500° C., for example, at about 100° C. to about 300° C. A more detailed description of the resist underlayer composition is not repeated here to avoid duplication because it has been described in more detail above.

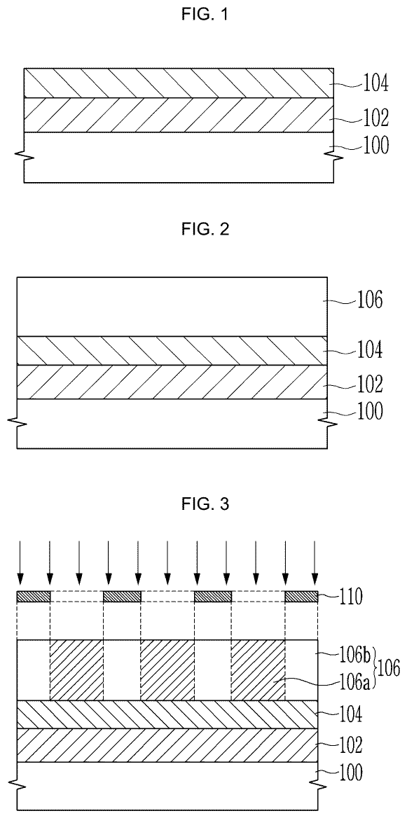

Referring to FIG. 2, a photoresist is coated on the resist underlayer 104 to form a photoresist layer 106.

Examples of the photoresist may be a positive-type photoresist containing a naphthoquinone diazide compound and a novolac resin, a chemically-amplified positive photoresist containing an acid generator capable of dissociating acid through exposure, a compound decomposed under presence of the acid and having increased dissolubility in an alkali aqueous solution, and an alkali soluble resin, a chemically-amplified positive-type photoresist containing an alkali-soluble resin capable of applying a resin increasing dissolubility in an alkali aqueous solution, and the like.

Subsequently, a first baking process is performed to heat the substrate 100 on which the photoresist layer 106 is formed. The first baking process may be performed at a temperature of about 90° C. to about 120° C.

Referring to FIG. 3, the photoresist layer 106 is selectively exposed. To explain the exposure process for exposing the photoresist layer 106 as an example, an exposure mask having a set or predetermined pattern is placed on the mask stage of an exposure apparatus, and an exposure mask 110 is placed on the photoresist layer 106. Subsequently, by irradiating light to the mask 110, a set or predetermined portion of the photoresist layer 106 formed on the substrate 100 selectively reacts with the light passing through the exposure mask.

For example, examples of light that can be used in the exposure process may include short-wavelength light such as i-line activating radiation having a wavelength of 365 nm, a KrF excimer laser having a wavelength of 248 nm, and an ArF excimer laser having a wavelength of 193 nm. In some embodiments, EUV (Extreme ultraviolet), which has a wavelength of 13.5 nm, which corresponds to extreme ultraviolet light, may be used.

An exposed region 106a of the photoresist layer 106 may be relatively hydrophilic compared to an unexposed region 106b of the photoresist layer 106. Accordingly, the exposed region 106a and unexposed region 106b of the photoresist layer 106 may have different solubilities from each other.

Subsequently, a second baking process is performed on the substrate 100. The second baking process may be performed at a temperature of about 90° C. to about 150° C. The exposed region of the photoresist layer becomes easily dissolvable in a set or predetermined solvent due to the secondary baking.

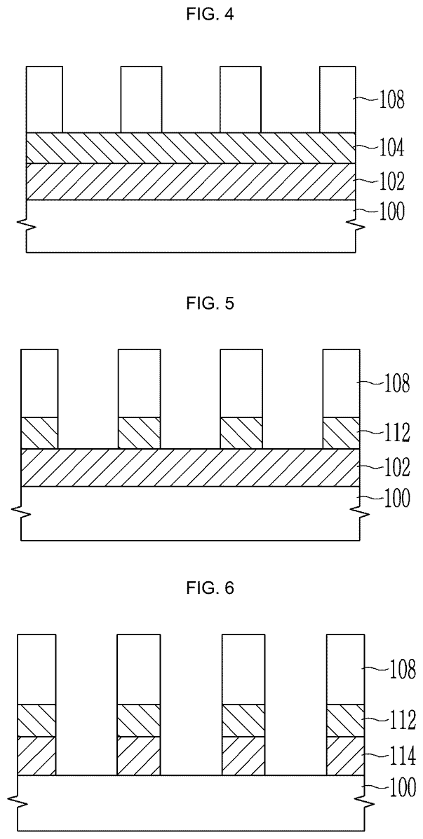

Referring to FIG. 4, as an example, the photoresist layer 106a corresponding to the exposed region is dissolved and then removed using tetra-methyl ammonium hydroxide (TMAH), etc., and the photoresist layer 106b remaining after development forms a photoresist pattern 108.

Subsequently, the resist underlayer 104 is etched using the photoresist pattern 108 as an etch mask. An organic film pattern 112 as shown in FIG. 5 is formed through the above etching process. The etching may be performed, for example, by dry etching using an etching gas, and the etching gas may be, for example, CHF₃, CF₄, Cl₂, O₂, or a mixture thereof. As described above, because the resist underlayer formed by the resist underlayer composition according to some embodiments has a fast etch rate, a smooth etching process can be performed within a short time.

Referring to FIG. 6, the exposed thin film 102 is etched by applying the photoresist pattern 108 as an etch mask. As a result, the thin film is formed into a thin film pattern 114. In the exposure process performed as described above, the thin film pattern formed by the exposure process performed using short-wavelength light sources such as the activating radiation i-line (wavelength: 365 nm), KrF excimer laser (wavelength: 248 nm), and ArF excimer laser (wavelength: 193 nm) 114) may have a width of tens to hundreds of nanometers and the thin film pattern 114 formed by an exposure process performed using an EUV light source may have a width of less than or equal to about 20 nm.

Hereinafter, embodiments of the present disclosure will be described in more detail through examples related to the synthesis of the aforementioned polymer and the preparation of a resist underlayer composition including the same. However, the present disclosure is not technically limited by the following examples.

### Synthesis of Polymers

### Synthesis Example 1

0.5 g of p-toluene sulfonic acid (PTSA), 30 g of 1,3,4,6-tetrakis(methoxymethyl)glycoluril (TMGU), 3 g of 1,2-ethanediol, and 150 g of 1,4-dioxane are added to a 500 mL 2-necked round bottom flask equipped with a condenser and then, reacted at 80° C. for 10 hours. After proceeding with the reaction, the resultant reaction solution is cooled to room temperature. Subsequently, triethylamine is added thereto to neutralize the reaction solution and then, purified to obtain Polymer 1 including a structural unit represented by Chemical Formula 2.

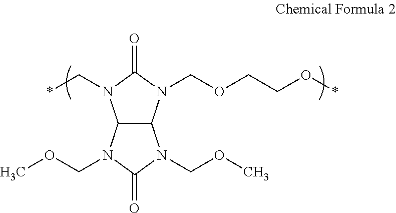

### Synthesis Example 2

Polymer 2 including a structural unit represented by Chemical Formula 3 is obtained in the same method as Synthesis Example 1 except that 6 g of succinic acid is used instead of the 1,2-ethanediol.

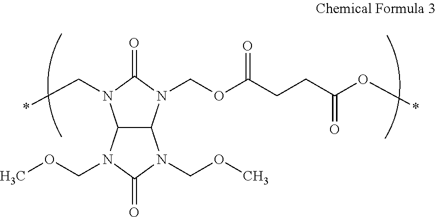

### Synthesis Example 3

Polymer 3 including a structural unit represented by Chemical Formula 4 is obtained in the same method as Synthesis Example 1 except that 45 g of 1,3,4,6-tetrakis(butoxymethyl)glycoluril instead of 30 g of the 1,3,4,6-tetrakis(methoxymethyl)glycoluril (TMGU) and 7.5 g of 2,3-dihydroxysuccinic acid instead of the 1,2-ethanediol are used.

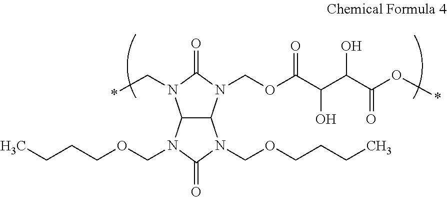

### Comparative Synthesis Example 1

20 g of 1,3-diallyl-5-(2,2-dimethyl)-isocyanurate, 6.0 g of 1,3-propanedithiol, 1 g of azobisisobutyronitrile (AIBN), and 50 g of N,N-dimethyl formamide are added to a 250 mL four-necked flask to prepare a reaction solution, and a condenser is connected thereto. The resultant reaction solution is heated at 50° C. for 5 hour to proceed with a reaction and then, cooled to room temperature. Subsequently, the reaction solution is dropped to a beaker containing 300 g of distilled water, while stirring, to produce gum, which is dissolved in 30 g of tetrahydrofuran (THF). The obtained resin solution is treated with toluene to form precipitates, from which single and low molecular weight molecules are removed to obtain a polymer including a structural unit represented by Chemical Formula 5 (a weight average molecular weight (Mw)=5,500 g/mol).

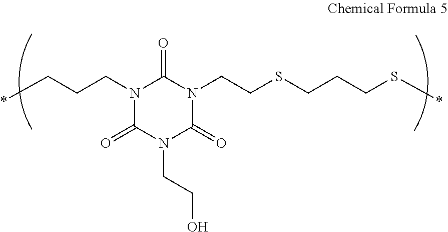

### Comparative Synthesis Example 2

148.6 g of 1,3,5-triglycidyl isocyanurate, 60.0 g of 2,2′-thiodiacetic acid, 9.1 g of benzyl triethyl ammonium chloride, and 350 g of N,N-dimethylformamide are added to a 1 L 2 necked round flask, and a condenser is connected thereto. After increasing the temperature to 100° C. and reacting them for 8 hours, the resultant reaction solution is cooled to room temperature (23° C.). Subsequently, the reaction solution is transported to a 1 L wide-mouthed bottle and then, three times washed with hexane and subsequently, with purified water. A resin obtained in a gum state therefrom is completely dissolved in 80 g of THF and then, slowly dropped to 700 g of toluene, while stirring. Subsequently, the solvent is removed therefrom to obtain a polymer (a weight average molecular weight (Mw)=8,200 g/mol) including a structural unit represented by Chemical Formula 6.

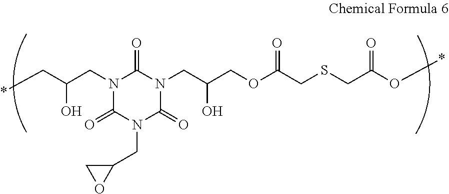

### Comparative Synthesis Example 3

0.5 g of p-toluene sulfonic acid (PTSA), 30 g of the polymer of Comparative Synthesis Example 1, 3 g of 1,3,4,6-tetrakis(methoxymethyl)glycoluril (TMGU), and 150 g of methyl 2-hydroxyisobutyrate are added to a 500 mL 2-necked round bottom flask equipped with a condenser and then, reacted at 80° C. for 2 hours. After proceeding with the reaction, the resultant reaction solution is cooled to room temperature. Subsequently, the reaction solution is neutralized by adding triethylamine thereto and then, purified to obtain a polymer (a weight average molecular weight (Mw)=6,200 g/mol) including a structural unit represented by Chemical Formula 7.

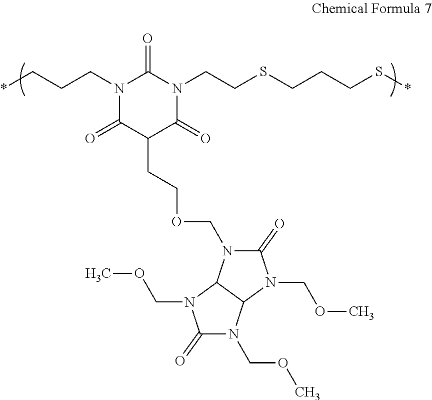

### Example 1

A resist underlayer composition is prepared by completely dissolving 0.1 g of the polymer of Synthesis Example 1, 0.01 g of pyridinium para-toluenesulfonate (PPTS) in 90 g of propylene glycol monomethylether and 5 g of ethyl lactate and then, additionally diluting the resultant solution with a solvent.

### Example 2

A resist underlayer composition is prepared in the same manner as in Example 1 except that the polymer of Synthesis Example 2 is used instead of the polymer of Synthesis Example 1.

### Example 3

A resist underlayer composition is prepared in the same manner as in Example 1 except that the polymer of Synthesis Example 3 is used instead of the polymer of Synthesis Example 1.

### Comparative Example 1

A resist underlayer composition is prepared by completely dissolving 0.5 g of the polymer of Comparative Synthesis Example 1, 0.15 g of PD1174 (a crosslinking agent, TCI), and 0.01 g of pyridinium para-toluenesulfonate (PPTS) in 90 g of propylene glycol monomethylether and 5 g of ethyl lactate and then, diluting the resultant solution by additionally using a solvent.

### Comparative Example 2

A resist underlayer composition is prepared in the same manner as in Comparative Example 1 except that the polymer of Comparative Synthesis Example 2 is used instead of the polymer of Comparative Synthesis Example 1.

### Comparative Example 3

A resist underlayer composition is prepared in the same manner as in Comparative Example 2 except that the PD1174 (a crosslinking agent, TCI) is not used.

### Comparative Example 4

A resist underlayer composition is prepared in the same manner as in Comparative Example 1 except that the polymer of Comparative Synthesis Example 3 is used instead of the polymer of Comparative Synthesis Example 1.

### Evaluation 1: Evaluation of Coating Uniformity

Each of the compositions of Examples 1 to 3 and Comparative Examples 1 to 4 is taken by 2 ml, cast on an 8-inch wafer and spin-coated at a main speed of 1,500 rpm for 20 seconds by using an auto track (ACT-8, TEL), and cured at 205° C. for 60 seconds to form a 50 Å-thick thin film.

Each thin film is measured with respect to a thickness at 51 points, from which a difference of a maximum thickness and a minimum thickness is calculated, as shown in Calculation Equation 1, to evaluate coating uniformity. The smaller the following coating uniformity value, the better the coating uniformity. Specifically, if the coating uniformity is less than 2 Å, “excellent” is given, if greater than or equal to 2 Å and less than 5 Å, “average” is given, and if greater than or equal to 5 Å, “inferior” is given. The results are shown in Table 1.

Coating uniformity (Å)=maximum thickness−minimum thickness among thicknesses measured at 51 points on the wafer Calculation Equation 1

TABLE 1

| | Coating uniformity (@thickness 50 Å) |
|---|---|
| Example 1 | Excellent |
| Example 2 | Excellent |
| Example 3 | Excellent |
| Comparative Example 1 | Excellent |
| Comparative Example 2 | Excellent |
| Comparative Example 3 | Inferior |
| Comparative Example 4 | Average |

Referring to Table 1, the resist underlayers formed of the compositions according to the examples exhibit smaller or equal coating uniformity to those formed of the compositions according to the comparative examples, which confirms that the compositions according to the examples has more excellent coating uniformity of resist underlayers than the compositions according to the comparative examples.

### Evaluation 2: Evaluation of Etch Rate

Each of the resist underlayer compositions according to Examples 1 to 3 and Comparative Examples 1 to 4 is spin-coated on a silicon wafer and heat-treated at 240° C. for 120 seconds to form thin films, which are measured with respect to a thickness. Subsequently, the thin films are dry-etched by using N₂/O₂ mixed gas for 60 seconds and then, measured again with respect to a thickness. In addition, the thin films are dry-etched for 100 seconds by using CFx gas and then, also measured with respect to a thickness. As shown in Calculation Equation 2, the thicknesses of the thin film before and after the dry etching are used with etching time to calculate an etch rate, and the other etch rates are relatively converted based on an etch rate of Example 1, and the results are shown in Table 2.

Etch rate (Å/s)=(Initial thin film thickness−Thin film thickness after etching)/Etching time Calculation Equation 2

TABLE 2

| | N₂/O₂ etch | CFx etch |
|---|---|---|
| Example 1 | 100 | 100 |
| Example 2 | 100 | 100 |
| Example 3 | 113 | 157 |
| Comparative Example 1 | 82 | 30 |
| Comparative Example 2 | 88 | 73 |
| Comparative Example 3 | 85 | 69 |
| Comparative Example 4 | 91 | 44 |

Referring to Table 2, the thin films formed of the resist underlayer compositions according to the examples have a higher etch rate than the thin films formed of the resist underlayer compositions according to the comparative examples.

### Evaluation 3: Evaluation of Contact Angle

The resist underlayer compositions according to Examples 1 to 3 and Comparative Examples 1 to 4 are respectively taken by 2 ml, cast on a 4-inch wafer, and spin-coated at 1,500 rpm for 20 seconds by using a spin coater (Mikasa Co., Ltd.). Subsequently, the coated compositions are cured at 210° C. for 90 seconds to form thin films and then, measured with respect to a contact angle by dropping distilled water (DIW) on the surface. The smaller the contact angle, the better adhesion with the resist, and the contact angle measurements are shown in Table 3.

TABLE 3

| | Contact angle (°) |
|---|---|
| Example 1 | 30 |
| Example 2 | 28 |
| Example 3 | 32 |
| Comparative Example 1 | 63 |
| Comparative Example 2 | 64 |
| Comparative Example 3 | 66 |
| Comparative Example 4 | 62 |

Referring to Table 3, the resist underlayers formed of the compositions according to the examples exhibit a low contact angle with the distilled water and excellent adhesion compared with the resist underlayers formed of the compositions according to the comparative examples.

### Evaluation 4: Evaluation of Chemical Resistance

The resist underlayer compositions according to Examples 1 to 3 and Comparative Examples 1 to 4 are respectively taken by 2 ml, cast on a 4-inch wafer, and spin-coated at 1,500 rpm for 20 seconds by spin coater (Mikasa Co., Ltd.). Subsequently, the coated compositions are cured at 210° C. for 90 seconds to form thin films, which are measured with respect to a thickness by using a film thickness meter manufactured by K-MAC. After dipping the thin films in a mixed solvent of ethyl 3-ethoxypropionate (EEP) and ethyl lactate (EL) (7:3 (v/v)) for 1 minute and taking them out, the thin films are measured again with respect to a thickness. A thickness reduction rate before and after the dipping is calculated, as shown in Calculation Equation 3, to evaluate chemical resistance of the underlayers. The smaller the thickness reduction rate, the better the chemical resistance. Specifically, if the thickness reduction rate is less than 2%, “excellent” is given, if greater than or equal to 2% and less than 5%, “average” is given, and if greater than or equal to 5%, “inferior” is given. The results are shown in Table 4.

Underlayer thickness reduction rate (%)={(thin film thickness before immersion−thin film thickness after immersion)/thin film thickness before immersion} Calculation Equation 3

TABLE 4

| | Thickness reduction rate (%) |
|---|---|
| Example 1 | Excellent |
| Example 2 | Excellent |
| Example 3 | Excellent |
| Comparative Example 1 | Excellent |
| Comparative Example 2 | Average |
| Comparative Example 3 | Inferior |
| Comparative Example 4 | Inferior |

From Table 4, the thickness reduction rates before and after immersion in the mixed solution of EEP and EL of the Examples are smaller than those of the Comparative Examples, and therefore, the chemical resistance of the resist underlayer according to the Examples is superior to those of the thin films according to the Comparative Examples.

Hereinbefore, example embodiments of the present disclosure have been described and illustrated, however, it should be apparent to a person having ordinary skill in the art that the present disclosure is not limited to the embodiment as described, and may be variously modified and transformed without departing from the spirit and scope of the present disclosure. Accordingly, the modified or transformed embodiments as such may not be understood separately from the technical ideas and aspects of the present disclosure, and the modified embodiments are within the scope of the claims of the present disclosure, and equivalents thereof.

### DESCRIPTION OF SYMBOLS

100: substrate 102: thin film
104: resist underlayer 106: photoresist layer
106a: exposed region 106b: unexposed region
108: photoresist pattern 110: mask
112: organic film pattern 114: thin film pattern

What is claimed is:

1. A resist underlayer composition, comprising:
a polymer comprising a structural unit represented by Chemical Formula 1, and a solvent: 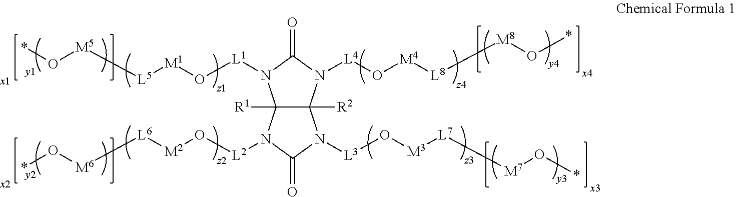
wherein, in Chemical Formula 1,
L¹ to L⁴ are each independently a substituted or unsubstituted C1 to C20 alkyl group or a substituted or unsubstituted C1 to C20 alkylene group,
L⁵ to L⁸ are each independently a single bond, a substituted or unsubstituted C1 to C20 alkyl group, a substituted or unsubstituted C1 to C20 alkylene group, a substituted or unsubstituted C2 to C20 alkenyl group, a substituted or unsubstituted C2 to C20 alkenylene group, a substituted or unsubstituted C2 to C20 alkynyl group, a substituted or unsubstituted C2 to C20 alkynylene group, a substituted or unsubstituted C3 to C20 cycloalkyl group, a substituted or unsubstituted C3 to C20 cycloalkylene group, a substituted or unsubstituted C6 to C30 aryl group, a substituted or unsubstituted C6 to C30 arylene group, or a combination thereof,
M¹ to M⁸ are each independently a single bond, —C(═O)—, —OC(═O)—, or a combination thereof,
x1 to x4 are each independently 0 or 1, provided that at least two selected from x1 to x4 are each 1,
y1 to y4 are each independently 0 or 1,
z1 to z4 are each independently 0 or 1,
R¹ and R² are each independently hydrogen, deuterium, a hydroxy group, a substituted or unsubstituted C1 to C10 alkoxy group, a substituted or unsubstituted C1 to C10 alkyl group, a substituted or unsubstituted C2 to C10 alkenyl group, a substituted or unsubstituted C2 to C10 alkynyl group, a substituted or unsubstituted C1 to C10 heteroalkyl group, a substituted or unsubstituted C1 to C10 heteroalkenyl group, a substituted or unsubstituted C1 to C10 heteroalkynyl group, a substituted or unsubstituted C3 to C20 cycloalkyl group, or a combination thereof, and
* is a linking point with other structural units.

2. The resist underlayer composition as claimed in claim 1, wherein in Chemical Formula 1, L¹ to L⁴ are each independently a substituted or unsubstituted C1 to C10 alkyl group or a substituted or unsubstituted C1 to C10 alkylene group, L⁵ to L⁸ are each independently a single bond, a substituted or unsubstituted C1 to C10 alkyl group, a substituted or unsubstituted C1 to C10 alkylene group, a substituted or unsubstituted C2 to C10 alkenyl group, a substituted or unsubstituted C2 to C10 alkenylene group, a substituted or unsubstituted C2 to C10 alkynyl group, a substituted or unsubstituted C2 to C10 alkynylene group, or a combination thereof,
M¹ to M⁸ are each independently a single bond, —C(═O)—, or a combination thereof,
two selected from x1 to x4 are each 1, the other two are 0, and
R¹ and R² are each independently hydrogen, deuterium, a hydroxy group, a substituted or unsubstituted C1 to C10 alkoxy group, a substituted or unsubstituted C1 to C10 alkyl group, or a combination thereof.

3. The resist underlayer composition as claimed in claim 1, wherein in Chemical Formula 1, L⁵ to L⁸ are each independently a single bond, a substituted or unsubstituted C1 to C10 alkyl group, a substituted or unsubstituted C1 to C10 alkylene group, or a combination thereof, M¹ to M⁸ are each independently a single bond, —C(═O)—, or a combination thereof, and R¹ and R² are hydrogen.

4. The resist underlayer composition as claimed in claim 1, wherein in Chemical Formula 1, x1 and x4 are each 1, and x2 and x3 are each 0.

5. The resist underlayer composition as claimed in claim 1, wherein the structural unit represented by Chemical Formula 1 is represented by one or more selected from Chemical Formula 1-1 and Chemical Formula 1-2: 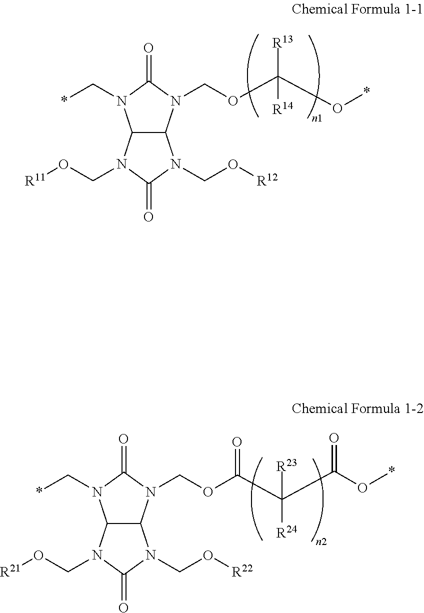
wherein, in Chemical Formula 1-1 and Chemical Formula 1-2,
R¹¹, R¹², R²¹, and R²² are each independently hydrogen, deuterium, or a substituted or unsubstituted C1 to C10 alkyl group,
R¹³, R¹⁴, R²³, and R²⁴ are each independently hydrogen, deuterium, a hydroxy group, a substituted or unsubstituted C1 to C10 alkyl group, a substituted or unsubstituted C1 to C10 alkoxy group, or a combination thereof,
n1 and n2 are each independently one selected from integers from 1 to 10, and
* is a linking point.

6. The resist underlayer composition as claimed in claim 1, wherein a weight average molecular weight of the polymer is about 1,000 g/mol to about 300,000 g/mol.

7. The resist underlayer composition as claimed in claim 1, wherein the polymer is included in an amount of about 0.1 wt % to about 50 wt % based on a total weight of the resist underlayer composition.

8. The resist underlayer composition as claimed in claim 1, wherein the resist underlayer composition further comprises one or more additional polymers selected from an acrylic resin, an epoxy resin, a novolac-based resin, a glycoluril-based resin, and a melamine-based resin.

9. The resist underlayer composition as claimed in claim 1, wherein the resist underlayer composition further comprises additives comprising a surfactant, a thermal acid generator, a photo acid generator, a plasticizer, or a combination thereof.

10. A method of forming a pattern, comprising:
forming a film to be etched on a substrate,
coating the resist underlayer composition as claimed in claim 1 on the film to be etched to form a resist underlayer,
forming a photoresist pattern on the resist underlayer, and
etching the resist underlayer and the film to be etched sequentially using the photoresist pattern as an etch mask.
